(19) United States
(12) Patent Application Publication
(10) Pub. No.: US 2026/0223532 A1
(43) Pub. Date: Jul. 30, 2026

(54) PREPARATION METHOD FOR DOPED METAL OXIDE, AND LIGHT-EMITTING DEVICE COMPRISING DOPED METAL OXIDE

(71) Applicant: TCL Technology Group Corporation, Huizhou, Guangdong (CN)

(72) Inventor: Kaimin CHEN, Huizhou, Guangdong (CN)

(73) Assignee: TCL Technology Group Corporation, Huizhou, Guangdong (CN)

(21) Appl. No.: 19/143,363

(22) PCT Filed: Nov. 2, 2023
(86) PCT No.: PCT/CN2023/129384

§ 371 Date: Jun. 25, 2025

(30) Foreign Application Priority Data
Dec. 27, 2022 (CN) 202211687816.7

(51) Int. Cl. H10K 50/16; H10K 50/115; H10K 71/60

(52) U.S. Cl. CPC H10K 50/16; H10K 50/115; H10K 71/60

(57) ABSTRACT

Disclosed are a preparation method for a doped metal oxide, and a light-emitting device including the doped metal oxide. The preparation method for the doped metal oxide uses a difference of solubility products between a hydroxide of a second metal element and a hydroxide of a first metal element in water to regulate a number of atoms of the second metal element doped into a crystal structure in different stages, such that the second metal element has a target differentiated distribution in the doped metal oxide to achieve a target energy level structure.

The application claims priority to Chinese Patent Application No. 202211687816.7, filed on Dec. 27, 2022, and entitled “PREPARATION METHOD FOR DOPED METAL OXIDE, LIGHT-EMITTING DEVICE COMPRISING DOPED METAL OXIDE, AND ELECTRONIC APPARATUS”, the entire contents of all of which are incorporated herein by reference.

### TECHNICAL FIELD

The present disclosure relates to a technical field of photoelectric technology, and in particular to a preparation method for a doped metal oxide, and a light-emitting device including the doped metal oxide.

### BACKGROUND

A metal oxide refers to a compound formed by a combination of a metal element and an oxygen element. The metal oxide is widely used in a high-efficiency catalyst, a battery, a light-emitting device, a supercapacitor, an energy storage device, a magnetic device and an optical device because of its ideal conductivity and chemical stability. In order to further improve a performance of the metal oxide, a doped metal oxide has become one of research hotspots in a field of materials. The doped metal oxide refers to an oxide including two or more metal elements, exhibiting characteristics of the metal elements included.

### TECHNICAL PROBLEM

At present, a solution-gel method for preparing a doped metal oxide includes: mixing precursors of various different metal elements with alkali in solution state for a reaction to obtain the doped metal oxide, but the solution-gel method has the following disadvantages: a distribution of one or more metal elements in the doped metal oxide prepared may not be regulated, thus it is inconvenient to regulate an energy level structure of the doped metal oxide, and then it is inconvenient to adaptively adjust the energy level structure of the doped metal oxide according to changes of application scenarios.

Therefore, how to realize the distribution of one or more metal elements in the doped metal oxide prepared may be regulated is of great significance to an application and development of the doped metal oxide.

### Technical Solutions

Accordingly, the present disclosure provides a preparation method for a doped metal oxide, and a light-emitting device including the doped metal oxide, so as to realize a differentiated distribution of one or more metal elements in the doped metal oxide prepared may be regulated.

In a first aspect, the present disclosure provides a preparation method for a doped metal oxide, including steps of:
providing a first solution including a first metal salt, a second solution including a second metal salt, and a third solution including an alkali, where the first metal salt includes a first metal element, and the second metal salt includes a second metal element; and
mixing the second solution, the third solution, water and the first solution for a reaction to obtain a doped metal oxide including the first metal element and the second metal element;
wherein a solubility product of a hydroxide of the second metal element in water is greater than a solubility product of a hydroxide of the first metal element in water at a same temperature.

In a second aspect, the present disclosure provides a doped metal oxide prepared by a preparation method as follows:
providing a first solution including a first metal salt, a second solution including a second metal salt, and a third solution including an alkali, where the first metal salt includes a first metal element, and the second metal salt includes a second metal element; and
mixing the second solution, the third solution, water and the first solution for a reaction to obtain a doped metal oxide including the first metal element and the second metal element;
wherein a solubility product of a hydroxide of the second metal element in water is greater than a solubility product of a hydroxide of the first metal element in water at a same temperature.

In a third aspect, the present disclosure provides a light-emitting device including:
an anode;
a cathode disposed opposite the anode;
an emission material layer disposed between the anode and the cathode; and
an electron functional layer disposed between the cathode and the emission material layer;
wherein a material of the electron functional layer includes a doped metal oxide prepared by a preparation method as follows:
providing a first solution including a first metal salt, a second solution including a second metal salt, and a third solution including an alkali, where the first metal salt includes a first metal element, and the second metal salt includes a second metal element; and
mixing the second solution, the third solution, water and the first solution for a reaction to obtain a doped metal oxide including the first metal element and the second metal element;
wherein a solubility product of a hydroxide of the second metal element in water is greater than a solubility product of a hydroxide of the first metal element in water at a same temperature.

### Advantageous Effects

In the preparation method for the doped metal oxide, a difference of solubility products between a hydroxide of a second metal element and a hydroxide of a first metal element in water is utilized to control a number of atoms of the second metal element doped into a crystal structure at different stages, such that the second metal element exhibits a target differentiated distribution in the doped metal oxide prepared to achieve a target energy level structure, and an energy level structure of the doped metal oxide may be adaptively adjusted according to changes of application scenarios, and a differentiated distribution of one or more metal elements in the doped metal oxide may be regulated.

### BRIEF DESCRIPTION OF THE DRAWINGS

In order to illustrate technical solutions in embodiments of the present disclosure more clearly, accompanying drawings involved in a description of the embodiments may be briefly described below. It may be apparent that the accompanying drawings in the following description are merely some of the embodiments of the present disclosure, and other drawings may be obtained according to these drawings for those skilled in the art without involving any inventive effort.

FIG. 1 is a flow chart schematic diagram of a preparation method for a doped metal oxide according to an embodiment of the present disclosure.

FIG. 2 is a schematic diagram of a structural composition of a doped metal oxide according to an embodiment of the present disclosure.

FIG. 3 is a schematic diagram of a structure of a first light-emitting device according to an embodiment of the present disclosure.

FIG. 4 is a schematic diagram of a structure of a second light-emitting device according to an embodiment of the present disclosure.

FIG. 5 is ultraviolet absorption spectrums of doped metal oxides prepared in Example 1, Comparative Example 1, and Comparative Example 2.

### DETAILED DESCRIPTION OF EMBODIMENTS

Embodiments of the present disclosure may be described clearly and fully below in connection with accompanying drawings in embodiments of the present disclosure. It may be apparent that the embodiments described are merely a part of embodiments of the present disclosure, rather than all the embodiments. Based on the embodiments in the present disclosure, all other embodiments obtained by a person skilled in the art without involving any inventive effort are within the scope of the present disclosure.

An embodiment of the present disclosure provides a quantum dot emission material layer, a preparation method thereof, and a quantum dot light-emitting diode. Hereinafter, each of them may be described in detail. An order of description of the following embodiments is not intended to limit a preferred order of embodiments. In addition, in a description of the present disclosure, a term “including/include” means “including but being not limited to/includes but is not limited to”. Terms such as “first”, “second”, “third”, etc. only serve to indicate, and do not impose numerical requirements or define order. Each embodiment of the present disclosure may be presented in a form of range. It should be understood that a description in the form of range is merely for convenience and brevity, and should not be construed as a limitation on a scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, a term “including/include(s)” means “including but being not limited to/include(s) but is not limited to”.

In the present disclosure, a term “and/or” is configured to describe an association relationship of associated objects, indicating that there may be three relationships. For example, “A and/or B” may indicate three cases: (1) A alone, (2) both A and B, or (3) B alone, where each of A and B may independently be singular or plural.

A term “at least one” refers to one or more, where “more” specifically denotes two or more. Terms “at least one”, “at least one of the following”, or similar expressions thereof refer to any combination of items listed, including any combination of a single item or multiple items. For example, “at least one of a, b, or c”, or “at least one of a, b, and c”, may all be expressed as: a, b, c, a-b (i.e., a and b), a-c, b-c, or a-b-c, where a, b, and c may independently be single or plural.

In the present disclosure, a term “A layer is formed on one side of B layer”, “A layer is formed on one side of B layer away from C layer”, or the like may be expressed that the A layer is directly formed on the side of the B layer or the side of the B layer away from the C layer, that is, the A layer is in direct contact with the B layer, or the A layer is indirectly formed on the side of the B layer or the side of the B layer away from the C layer, that is, another spacer structure layer may be formed between the A layer and the B layer. Similarly, “the A layer is disposed on one side of the B layer” and “A layer is disposed on one side of B layer away from C layer” may be indicated that the A layer is in direct contact with the B layer, or that another spacer structure layer is disposed between the A layer and the B layer. “A layer is disposed between the B layer and the C layer” may mean that the A layer is in direct contact with the B layer and the A layer is in direct contact with the C layer, or the A layer is in direct contact with the B layer and one or more spacer structural layers are disposed between the A layer and the C layer, or one or more spacer structural layers are disposed between the A layer and the B layer and one or more spacer structural layers are disposed between the A layer and the C layer, or one or more spacer structural layers are disposed between the A layer and the B layer and the A layer is in direct contact with the C layer.

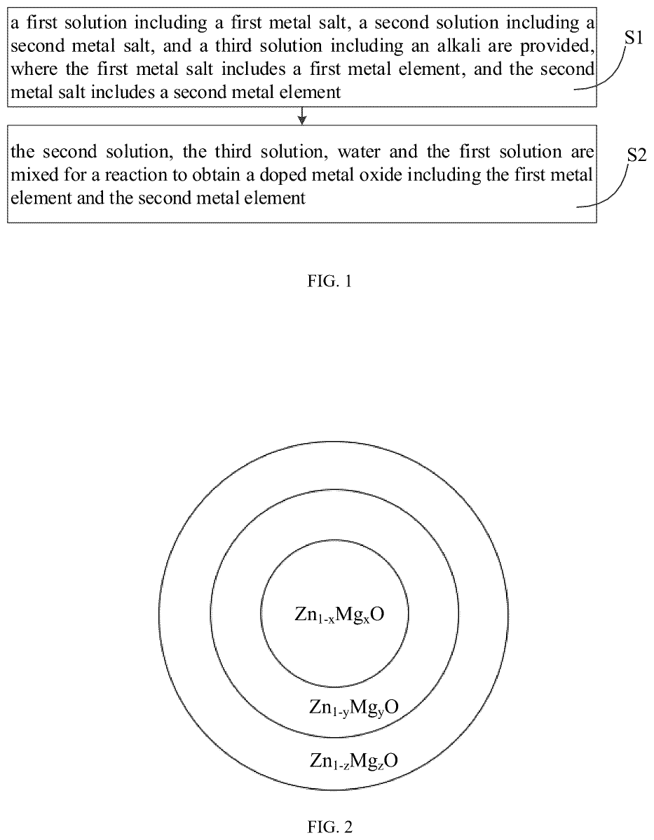

An embodiment of the present disclosure provides a preparation method for a doped metal oxide. Referring to FIG. 1, the preparation method includes step S1 and step S2.

In step S1, a first solution including a first metal salt, a second solution including a second metal salt, and a third solution including an alkali are provided, where the first metal salt includes a first metal element, and the second metal salt includes a second metal element.

In step S2, the second solution, the third solution, water and the first solution are mixed for a reaction to obtain a doped metal oxide including the first metal element and the second metal element.

At a same temperature, a solubility product of a hydroxide of the second metal element in water is greater than that of a hydroxide of the first metal element, that is, a solubility of the hydroxide of the second metal element in water is greater than that of the hydroxide of the first metal element in water, and a difference of solubility products between the hydroxide of the second metal element and the hydroxide of the first metal element in water is utilized to regulate a number of atoms of the second metal element doped into a crystal structure at different stages, such that the second metal element exhibits a target differentiated distribution in the doped metal oxide prepared.

In step S1, an anion constituting the first metal salt and an anion constituting the second metal salt include, but are not limited to, a halide ion, a sulfate ion, a carbonate ion, a nitrate ion, a phosphate ion or a carboxylate ion. In a case where the first metal element is Zn, the first metal salt includes, but is not limited to, one or more of zinc halide, zinc acetate, zinc nitrate, and zinc sulfate. In a case where the second metal element is Mg, the second metal salt includes, but is not limited to, one or more of magnesium halide, magnesium acetate, magnesium nitrate, and magnesium sulfate.

In step S1, as an example, the first metal element is selected from Zn, and the second metal element is selected from Mg, Ca, Mn, or Ba. As another example, the first metal element is selected from Al, and the second metal element is selected from Zn, Mg, Ca, Mn, Ba, or Sn. As another example, the first metal element is selected from Sn, and the second metal element is selected from Zn, Mg, Ca, Mn, or Ba. As another example, the first metal element is selected from Ti, and the second metal element is selected from Zn, Mg, Ca, Mn, Ba, Sn, or Al.

In some embodiments, a concentration of the first metal salt in the first solution ranges from 0.1 mmol/mL to 0.5 mmol/mL, for example, may be in a range of 0.1 mmol/mL to 0.2 mmol/mL, in a range of 0.2 mmol/mL to 0.3 mmol/mL, in a range of 0.3 mmol/mL to 0.4 mmol/mL, or in a range of 0.4 mmol/mL to 0.5 mmol/mL. A concentration of the second metal salt in the second solution ranges from 0.1 mmol/mL to 0.5 mmol/mL, for example, may be in a range of 0.1 mmol/mL to 0.2 mmol/mL, in a range of 0.2 mmol/mL to 0.3 mmol/mL, in a range of 0.3 mmol/mL to 0.4 mmol/mL, or in a range of 0.4 mmol/mL to 0.5 mmol/mL.

In step S1, the alkali in the third solution includes but is not limited to one or more of potassium hydroxide, sodium hydroxide, lithium hydroxide, tetraalkylammonium hydroxide, ethanolamine, diethanolamine, triethanolamine, aqueous ammonia, ethylenediamine, tetramethylammonium hydroxide, tetraethylammonium hydroxide, tetrapropylammonium hydroxide, tetrabutylammonium hydroxide, and tetraalkylammonium hydroxide (TAAOH, alkyl=methyl, ethyl, propyl, and butyl).

In some embodiments, a concentration of the alkali in the third solution ranges from 0.1 mmol/mL to 1.0 mmol/mL, for example, may be in a range of 0.1 mmol/mL to 0.2 mmol/mL, in a range of 0.2 mmol/mL to 0.3 mmol/mL, in a range of 0.3 mmol/mL to 0.4 mmol/mL, in a range of 0.4 mmol/mL to 0.5 mmol/mL, in a range of 0.5 mmol/mL to 0.6 mmol/mL, in a range of 0.6 mmol/mL to 0.7 mmol/mL, in a range of 0.7 mmol/mL to 0.8 mmol/mL, in a range of 0.8 mmol/mL to 0.9 mmol/mL, or in a range of 0.9 mmol/mL to 1.0 mmol/mL.

Solvents of the first solution, the second solution, and the third solution are each independently selected from an organic solvent, including, but not limited to, one or more of alkanes, aromatic hydrocarbons, halogenated alkanes, alcohol compounds, ether compounds, furan compounds, pyridine compounds, and amide compounds, and examples thereof include one or more of methanol, ethanol, propanol, butanol, ethylene glycol, ethylene glycol monomethyl ether, dimethyl sulfoxide, and N, N-dimethylformamide.

In order to further improve a performance controllability of the doped metal oxide, in some embodiments, a conduction band of a first metal oxide formed by the first metal element is smaller than a conduction band of a second metal oxide formed by the second metal element.

In order to further improve an effect that the second metal element exhibits a target differentiated distribution in the doped metal oxide prepared, in some embodiments, step S2 includes a step that the second solution, the third solution, and water are injected into the first solution, where the second solution, the third solution and the water are injected at a same start time and a same end time, and during an injection process, the second solution and the third solution are each injected at a uniform rate, while the water is injected at a non-uniform rate. By adjusting an injection rate of the water such that the water is not uniformly injected into the first solution, while the second solution and the third solution are uniformly injected into the first solution, and by controlling start times and end times of injections of the second solution, the third solution, and the water to be identical with each other, a difference of solubility products between a hydroxide of a second metal element and a hydroxide of a first metal element in water is utilized to adjust the number of atoms of the second metal element doped into the crystal structure at different stages, thus the second metal element exhibits a target differentiated distribution in the doped metal oxide prepared to achieve the target energy level structure, and it is convenient to adaptively adjust the energy level structure of the doped metal oxide according to changes of application scenario.

Specifically, the preparation method for the doped metal oxide is to control a proportion of two connection modes between the second metal element and a hydroxyl group by regulating a water content in a reaction system, where the two connection modes are an ionic bond connection mode and a covalent bond connection mode, so as to control the number of atoms of the second metal element doped into the crystal structure at different stages. More specifically, when the first metal element is M and the second metal element is A, in a process of preparing the doped metal oxide, a condensation reaction shown in the following formulas (I) to (III) mainly occur:

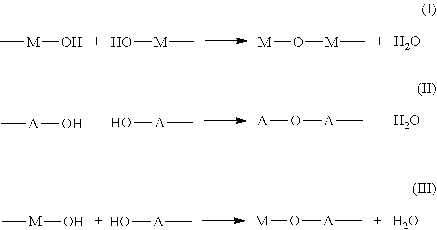

When water is injected into the reaction system, since the solubility product of the hydroxide of the second metal element in water is greater than that of the hydroxide of the first metal element at the same temperature, -A-OH reacts with water more easily than -M-OH to generate A ions and OH—, thereby reducing an amount of -A-OH participating in reactions (III) and (II), and decreasing a number of A atoms doped into the crystal structure. Therefore, by adjusting a water injection rate, the number of A atoms doped into the crystal structure may be regulated, enabling the second metal element to exhibit a targeted differential distribution in the doped metal oxide prepared.

In order to further improve the performance controllability of the doped metal oxide, in a step of mixing the second solution, the third solution, the water and the first solution, a molar ratio of the second metal element in the second solution to the first metal element in the first solution ranges from ranges from 1:4 to 1:20, for example, in a range of 1:4 to 1:6, in a range of 1:6 to 1:8, in a range of 1:8 to 1:10, in a range of 1:10 to 1:12, in a range of 1:12 to 1:15, in a range of 1:15 to 1:18, or in a range of 1:18 to 1:20. And/or, a molar ratio of the second metal element in the second solution to the water ranges from 1:4 to 1:20, for example, in a range of 1:4 to 1:6, in a range of 1:6 to 1:8, in a range of 1:8 to 1:10, in a range of 1:10 to 1:12, in a range of 1:12 to 1:15, in a range of 1:15 to 1:18, or in a range of 1:18 to 1:20. And/or, a molar ratio of the first metal element in the first solution to hydroxyl of the alkali in the third solution ranges from 1:0.8 to 1:4, for example, in a range of 1:0.8 to 1:1, in a range of 1:0.8 to 1:2, in a range of 1:1 to 1:2, in a range of 1:2 to 1:3, or in a range of 1:3 to 1:4, and when a valence state of the first metal element is two, the molar ratio of the first metal element in the first solution to hydroxyl of the alkali in the third solution ranges from 1:0.8 to 1:2.

In some embodiments, a final injection rate of the water is greater than an initial injection rate of the water, so that a molar percentage of the second metal element in a surface of the doped metal oxide is less than a molar percentage of the second metal element in an interior of the doped metal oxide in the doped metal oxide prepared.

In some embodiments, in step S2, during a process of injecting the water, an injection rate of the water gradually increases, so that in the doped metal oxide, a molar percentage of the second element gradually decreases in a direction from the interior to the surface of the doped metal oxide. Taking the first metal element selected from Zn and the second metal element selected from Mg as an example, the doped metal oxide prepared is shown in FIG. 2, where 1>x>y>z≥0.

As used herein, “gradually increase(s)”, “gradually decrease(s)” or the like should be understood broadly, that is, during a process of injection, the injection rate of water may increase gradually in a stepped manner or in a continuous manner. Similarly, along a radial direction from the interior to the surface of the doped metal oxide, the molar percentage of the second metal element may gradually increase in a stepped manner or in a continuous manner.

In some embodiments, in step S2, the final injection rate of the water is 1.5 to 3 times the initial injection rate of the water, for example, may be from 1.5 times to 1.8 times, from 1.8 times to 2.0 times, from 2.0 times to 2.2 times, from 2.2 times to 2.4 times, from 2.4 times to 2.6 times, from 2.6 times to 2.8 times, or from 2.8 times to 3.0 times.

Alternatively, in some embodiments, a final injection rate of the water is less than an initial injection rate of the water, so that a molar percentage of the second metal element in a surface of the doped metal oxide is greater than a molar percentage of the second metal element in an interior of the doped metal oxide in the doped metal oxide prepared. Taking the first metal element selected from Zn and the second metal element selected from Mg as an example, the doped metal oxide prepared is shown in FIG. 2, where 1>z≥y>x>0.

In some embodiments, in step S2, during a process of injecting the water, an injection rate of the water gradually decreases, so that in the doped metal oxide, a molar percentage of the second element gradually increases along a radial direction from the interior to the surface of the doped metal oxide. During the process of injecting the water, the injection rate of the water may gradually decrease in a stepped manner or in a continuous manner. In the doped metal oxide, along a radial direction from the interior to the surface of the doped metal oxide, a molar percentage of the second element gradually increases in a stepped manner or in a continuous manner.

In some embodiments, in step S2, the initial injection rate of the water is 1.5 to 3 times the final injection rate of the water, for example, may be from 1.5 times to 1.8 times, from 1.8 times to 2.0 times, from 2.0 times to 2.2 times, from 2.2 times to 2.4 times, from 2.4 times to 2.6 times, from 2.6 times to 2.8 times, or from 2.8 times to 3.0 times.

In order to further improve the performance controllability of the doped metal oxide, in step S2, a total time of injection ranges from 5 minutes to 60 minutes, for example, may be from 5 minutes to 10 minutes, from 10 minutes to 20 minutes, from 20 minutes to 30 minutes, from 30 minutes to 40 minutes, from 40 minutes to 50 minutes, or from 50 minutes to 60 minutes.

In order to further improve the performance controllability of the doped metal oxide, in step S2, the reaction is performed at a temperature ranging from 0° C. to 70° C., for example, may be from 0° C. to 10° C., from 10° C. to 20° C., from 20° C. to 30° C., from 30° C. to 40° C., from 40° C. to 50° C., from 50° C. to 60° C., or from 60° C. to 70° C. And/or, a time of the reaction ranges from 5 minutes to 24 hours, for example, may be from 5 minutes to 30 minutes, from 30 minutes to 1 hour, from 1 hour to 2 hours, from 2 hours to 3 hours, from 3 hours to 4 hours, from 5 hours to 6 hours, from 6 hours to 7 hours, from 7 hours to 10 hours, from 10 hours to 12 hours, from 12 hours to 15 hours, from 15 hours to 20 hours, or from 20 hours to 24 hours. For example, the reaction includes a step of stirring at 0° C. to 70° C. for 5 minutes to 24 hours.

In order to obtain the doped metal oxide in a solid state, in some embodiments, after the reaction of step S2, the preparation method for the doped metal oxide further includes a step in which a precipitant is added to a product of the reaction to form a precipitate, and then a solid-liquid separation is performed to collect the precipitate. The precipitate is a purified doped metal oxide. Among them, the precipitant includes, but is not limited to, heptane. The solid-liquid separation includes, but is not limited to, one or more of sedimentation, filtration, and evaporation. The sedimentation includes, but is not limited to, one or more of gravity sedimentation, centrifugal sedimentation, and electromagnetic sedimentation. The filtration separation includes, but is not limited to, one or more of reverse osmosis, membrane filtration, nanofiltration, ultrafiltration, and microfiltration.

An embodiment of the present disclosure also provides a doped metal oxide, where the doped metal oxide is prepared by any one of preparation methods for a doped metal oxide described above. It is understood that the doped metal oxide includes a first metal element and a second metal element, and when the final injection rate of the water is greater than the initial injection rate of the water, the molar percentage of the second metal element in the surface of the doped metal oxide is less than the molar percentage of the second metal element in the interior of the doped metal oxide. When the injection rate of water gradually increases during a preparation of the doped metal oxide, along a radial direction from the interior to the surface of the doped metal oxide, the molar percentage of the second metal element gradually decreases. When the final injection rate of the water is less than the initial injection rate of water during a preparation of the doped metal oxide, the molar percentage of the second metal element in the surface of the doped metal oxide is greater than the molar percentage of the second metal element in the interior of the doped metal oxide. When the injection rate of the water gradually decreases during a preparation of the doped metal oxide, along a radial direction from the interior to the surface of the doped metal oxide, the molar percentage of the second metal element gradually increases.

In some embodiments, an average particle size of the doped metal oxide ranges from 2 nm to 20 nm, for example, may be from 2 nm to 5 nm, from 5 nm to 8 nm, from 8 nm to 10 nm, from 10 nm to 15 nm, or from 15 nm to 20 nm. And/or, a band gap of the doped metal oxide ranges from 3.7 eV to 4.5 eV, for example, may be from 3.7 eV to 3.8 eV, from 3.8 eV to 3.9 eV, from 3.8 eV to 3.9 eV, from 3.9 eV to 4.0 eV, from 4.0 eV to 4.1 eV, from 4.1 eV to 4.2 eV, from 4.2 eV to 4.3 eV, from 4.3 eV to 4.4 eV, or from 4.4 eV to 4.5 eV.

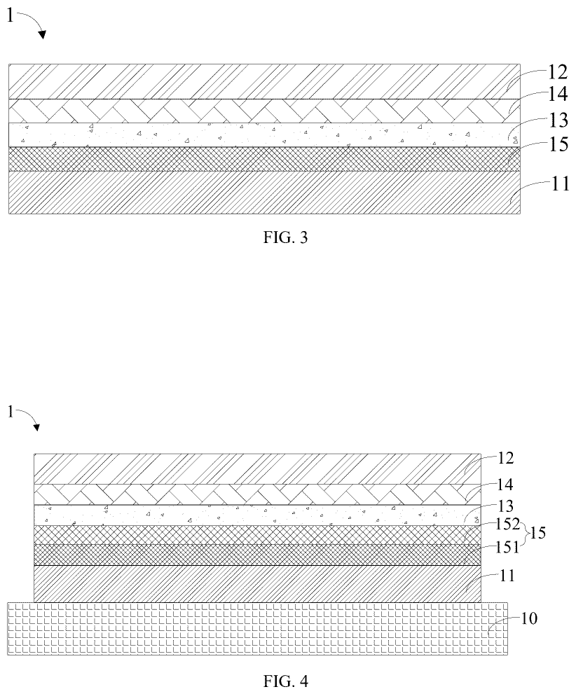

An embodiment of the present disclosure also provides a light-emitting device. Referring to FIG. 3, the light-emitting device 1 includes an anode 11, a cathode 12, an emission material layer 13, and an electron functional layer 14. The anode 11 and the cathode 12 are disposed opposite each other, the emission material layer 13 is disposed between the anode 11 and the cathode 12, and the electron functional layer 14 is disposed between the cathode 12 and the emission material layer 13.

In a conventional light-emitting device, a metal oxide may be used as a material of the electron functional layer, and in order to further improve a performance of a light-emitting device, a doped metal oxide may be configured to prepare the electron functional layer. However, the doped metal oxide prepared by a conventional preparation method (e.g., a solution-gel method) has shortcomings: it is difficult to regulate a distribution of one or more metal elements in the doped metal oxide prepared, so it is not convenient to adaptively adjust an energy level structure of the doped metal oxide according to requirements of a light-emitting device, resulting in an unsatisfactory performance of a light-emitting device.

For example, when a light-emitting device is a quantum dot light-emitting diode, zinc oxide is a common electronically functional material. Zinc oxide has a conduction band energy level that facilitates electron injection from a cathode into an emission material layer, and its deep valence band energy level provides a hole-blocking function. Doping an appropriate amount of magnesium into zinc oxide may effectively mitigate a fluorescence quenching phenomenon of quantum dots, thereby enhancing a current efficiency of a light-emitting device. However, doped magnesium may affect an energy level structure and an electron mobility of zinc oxide, and an excessively high doping level of magnesium may cause a conduction band energy level of zinc oxide to rise, thereby increasing an electron injection barrier and hindering electron injection. A conventional solution-gel method for preparing a magnesium-doped zinc oxide includes the following steps: a solution including a magnesium precursor and an alkali solution are injected into a solution including a zinc precursor, followed by a mixing reaction to obtain a magnesium-doped zinc oxide. Theoretically, along a radial direction from an interior to a surface of the magnesium-doped zinc oxide prepared, a molar percentage difference of a second metal element is very small, and a distribution of magnesium in the magnesium-doped zinc oxide may not be regulated, so that a molar percentage of magnesium in the magnesium-doped zinc oxide prepared is often high, resulting in difficulty in electron injection and an unsatisfactory photoelectric performance of a light-emitting device.

In the light-emitting device of the embodiment of the present disclosure, a material of the electron functional layer 14 includes a doped metal oxide, the doped metal oxide is prepared by the preparation method of a doped metal oxide described above. The doped metal oxide includes the first metal element and the second metal element, and the second metal element exhibits a target differentiated distribution in the doped metal oxide, so that an energy level structure of the doped metal oxide may adaptively meet requirements of the light-emitting device which is beneficial for improving a photoelectric performance of the light-emitting device.

As an example, a magnesium-doped zinc oxide may be used as the material of the electron functional layer 14, and a molar percentage of magnesium in a surface of the magnesium-doped zinc oxide is smaller than a molar percentage of magnesium in an interior of the magnesium-doped zinc oxide. Preferably, along a radial direction from the interior to the surface of the magnesium-doped zinc oxide, the molar percentage of magnesium gradually decreases which has advantages: on the one hand, constructing a varying energy level structure (such as a stepped energy level structure) between the electron functional layer and the cathode is beneficial to electron injection and improves an electron injection level of the light-emitting device, on the other hand, compared with zinc oxide, a band gap of the magnesium-doped zinc oxide is wider which is more conducive to limiting excitons to the emission material layer for recombination, thereby improving a current efficiency of the light-emitting device.

The electron functional layer 14 may have a single-layer structure or a multilayer structure, and a thickness of the electron functional layer 14 is, for example, in a range of 10 nm to 100 nm. When the electron functional layer 14 has a single-layer structure, the electron functional layer 14 is, for example, an electron injection layer or an electron transport layer. When the electron functional layer 14 has a multilayer structure, the electron functional layer 14 includes an electron injection layer and an electron transport layer disposed in stack, the electron transport layer is closer to the emission material layer 13 than the electron injection layer, the electron injection layer is closer to the cathode 12 than the electron transport layer, and a material of the electron injection layer is a doped metal oxide and/or a material of the electron transport layer is a doped metal oxide, and the doped metal oxide is prepared by the preparation method for a doped metal oxide described above.

In the light-emitting device 1 of an embodiment of the present disclosure, materials of the anode 11, the cathode 12, and the emission material layer 13 may be common materials in the art.

Materials of the anode 11 and the cathode 12 are independently selected from one or more of a metal, a carbon material, and a third metal oxide. The metal is selected from one or more of Al, Ag, Cu, Mo, Au, Ba, Ca, and Mg. The carbon material is selected from one or more of graphite, carbon nanotubes, graphene, and carbon fibers. The third metal oxide may be a doped or undoped metal oxide, for example, the third metal oxide is selected from one or more of indium-doped tin oxide (ITO), fluorine-doped tin oxide (FTO), antimony-doped tin oxide (ATO), aluminum-doped zinc oxide (AZO), gallium-doped zinc oxide (GZO), indium-doped zinc oxide (IZO), and magnesium-doped zinc oxide (MZO). The anode 11 or the cathode 12 may also be a composite electrode with the metal sandwiched between doped or undoped transparent metal oxides, including but not limited to one or more of AZO/Ag/AZO, AZO/AI/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂. A thickness of the anode 11 may be, for example, in a range of 20 nm to 200 nm, and a thickness of the cathode 12 may be, for example, in a range of 20 nm to 200 nm.

A material of the emission material layer 13 may be selected from an organic light-emitting material or a quantum dot, the light-emitting device 1 is an OLED or a QLED correspondingly, and a thickness of the emission material layer 13 may be, for example, in a range of 10 nm to 50 nm. The emission material layer 13 may have a single-layer structure or a multilayer structure, and for example, the emission material layer 13 may have two or more layers.

The organic light-emitting material includes, but is not limited to, one or more of 4, 4′-bis (N-carbazole)-1, 1′-biphenyl: tris [2-(p-tolyl) pyridinate iridium (III), 4, 4′, 4′-tris (carbazol-9-yl) triphenylamine: tris [2-(p-tolyl) pyridinate iridium, a diarylanthracene derivative, a stilbene aromatic derivative, a pyrene derivative, a fluorene derivative, a TBPe fluorescent material, a TTPX fluorescent material, a TBRb fluorescent material, a DBP fluorescent material, a delayed fluorescent material, a TTA material, a thermally activated delayed material, a polymer including a B-N covalent bond, a hybrid local charge transfer excited state material, and an exciplex luminescent material.

The quantum dot includes, but is not limited to, one or more of a red quantum dot, a green quantum dot, and a blue quantum dot, and the quantum dot includes, but is not limited to, one or more of a quantum dot with a single component, a quantum dot with a core-shell structure, an inorganic perovskite quantum dot, an organic perovskite quantum dot, and an organic-inorganic hybrid perovskite quantum dot. An average particle size of the quantum dot may be, for example, in a range of 5 nm to 10 nm, such as 5 nm, 6 nm, 7 nm, 8 nm, 9 nm, or 10 nm.

For the quantum dot with the single component or the quantum dot with the core-shell structure, a material of the quantum dot with a single component, a material of a core of the quantum dot with the core-shell structure, and a material of a shell layer of the quantum dot with a core-shell structure includes, but is not limited to, at least one of a group II-VI compound, a group III-V compound, a group IV-VI compound, or a group I-III-VI compound. The group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, HgSeS, HgSeTe, CdZnS, CdZnSe, CdHgTe, HgZnS, HgZnSe, HgZnTe, CdZnSeS, CdHgSeTe, CdHgSTe, HgZnSeS, HgZnSeTe, and HgZnSTe, the Group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, InNSb, InPAs, InPSb, GaAlNP, GaAlNAs, GaAlNSb, GaAlPAs, GaAlPSb, InAlNP, InAlNAs, InAlNSb, InAlPAs and InAlPSb, the Group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, and the Group I-III-VI compound is selected from one or more of CuInS, CuInSe, and AgInS. For the material of the quantum dot with a single component, the material of a core of the quantum dot with a core-shell structure, and the material of a shell layer of the quantum dot with a core-shell structure, a chemical formula provided only indicates an elemental composition and does not indicate a content of each element. For example, CdZnSe only indicates that it is composed of three elements, Cd, Zn, and Se. If the content of each element is to be indicated, it may correspondingly be CdₓZn₁₋ₓSe, where 0<x<1.

The inorganic perovskite quantum dot has a general structural formula of AMX₃, where A is Cs⁺, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

The organic perovskite quantum dot has a general structural formula of CMX₃, where C is a formamidyl, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

The organic-inorganic hybrid perovskite quantum dot has a general structural formula of BMX₃, where B is an organic amine cation including but being not limited to CH₃(CH₂)ₙ₋₂NH³⁺ or NH₃(CH₂)ₙNH₃²⁺, n is greater or equal to 2, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

When the material of the emission material layer includes the quantum dot, the material of the emission material layer further includes a ligand attached to a surface of the quantum dot. The ligand includes, but is not limited to, at least one of an amine ligand, a carboxylic acid ligand, a thiol ligand, a (oxy) phosphine ligand, a phospholipid, a soft phospholipid, or polyvinylpyridine. The amine ligand is, for example, selected from at least one of methylamine, ethylamine, propylamine, butylamine, pentylamine, hexylamine, octylamine, nonylamine, decylamine, dodecylamine, cetylamine, stearylamine, dimethylamine, diethylamine, dipropylamine, tributylamine, or trioctylamine. The carboxylic acid ligand is, for example, selected from at least one of formic acid, acetic acid, propionic acid, butyric acid, valeric acid, caproic acid, enanthic acid, caprylic acid, lauric acid, palmitic acid, stearic acid, oleic acid, or benzoic acid. The thiol ligand is, for example, selected from at least one of methanethiol, ethanethiol, propanethiol, butanethiol, pentanethiol, hexanethiol, octanethiol, dodecanethiol, hexadecanethiol, octadecanethiol, or benzyl mercaptan. The (oxy)phosphine ligand is selected from, for example, at least one of methylphosphine, ethylphosphine, propylphosphine, butylphosphine, pentylphosphine, octylphosphine, dioctylphosphine, tributylphosphine, or trioctylphosphine.

In order to further improve a comprehensive performance of the light-emitting device, in some embodiments, referring to FIG. 3, the light-emitting device 1 further includes a hole functional layer 15 disposed between the emission material layer 13 and the anode 11.

The hole functional layer 15 may have a single-layer structure or a multilayer structure, and a thickness of the hole functional layer 15 is, for example, in a range of 10 nm to 100 nm. In some embodiments, the hole functional layer 15 has a single-layer structure, and the hole functional layer 15 is, for example, a hole injection layer or a hole transport layer.

In other embodiments, the hole functional layer 15 has a multilayer structure. The hole functional layer 15 includes a hole injection layer and a hole transport layer disposed in stack, where the hole injection layer is closer to the anode 11 than the hole transport layer, and the hole transport layer is closer to the emission material layer 13 than the hole injection layer.

A material of the hole injection layer and/or a material of the hole transport layer is selected from one or more of poly (3, 4-ethylenedioxythiophene)-poly (styrenesulfonate), copper(II) phthalocyanine, titanyl phthalocyanine, poly (9,9-dioctylfluorene-co-N-(4-butylphenyl) diphenylamine), poly (3-hexylthiophene-2,5-diyl), poly (n-vinylcarbazole), poly [N, N′-bis (4-butylphenyl)-N, N′-bis (phenyl)-benzi, poly (N, N′-bis (4-butylphenyl)-N, N′-diphenyl-1,4-benzenediamine-co-9,9-dioctylfluorene, poly [4, 4′, 4″-tris (N-3-methylphenyl-N-phenylamino) triphenylamine], poly [4, 4′, 4″-tris[2-naphthyl (phenyl) amino] triphenylamine], 2, 3, 5, 6-tetrafluoro-7, 7, 8, 8-tetracyanoquinodimethane, hexaazatriphenylenehexacabonitrile, poly (4, 4′-N, N′-dicarbazolyl-biphenyl), poly (4, 4′-bis (1-naphthyl)-1, 1′-biphenyl-4, 4′-diamine), poly (4, 4′-Bis (N-carbazolyl)-1, 1′-biphenyl), poly (4, 4′, 4″-tris (carbazol-9-yl)triphenylamine), poly (N, N′-diphenyl-N, N′-bis (3-methylphenyl)-(1,1′-biphenyl)-4,4′-diamine), poly (N,N′-bis (3-methylphenyl)-N, N′-bis (phenyl)-spiro), poly (N, N′-bis (4-(N, N′-diphenyl-amino)phenyl)-N, N′-diphenylbenzidine), poly (4, 4′, 4′-tris (N-carbazolyl)-triphenylamine), poly[4, 4′, 4″-tris (N-3-methylphenyl-N-phenylamino) triphenylamine], poly (9,9-dioctylfluorene-co-N-(4-butylphenyl) diphenylamine), poly (4-butylphenyl-diphenylamine), polyaniline, polypyrrole, poly (p) phenylene vinylidene, poly (phenylenevinylene), poly(2-methoxy-5-(2-ethylhexyloxy)-1, 4-phenylenevinylene), poly(2-methoxy-5-(3′, 7′-dimethyloctyloxy)-1, 4-phenylenevinylene), aromatic tertiary amines, 4, 4′-bis (p-carbazolyl)-1, 1′-biphenyl, N, N, N′, N′-tetraarylbenzidine, poly (N-vinylcarbazole) and its derivatives, polymethacrylates and its derivatives, poly (9,9-octylfluorene) and its derivatives, poly (spirofluorene) and its derivatives, poly (N, N′-bis (naphthalen-1-yl)-N, N′-diphenylbenzidine, doped or undoped graphene, C60, doped or undoped nickel oxide, doped or undoped molybdenum oxide, doped or undoped tungsten oxide, doped or undoped vanadium oxide, doped or undoped P-type gallium nitride, doped or undoped chromium oxide, doped or undoped copper oxide, a transition metal sulfide, and a transition metal selenide. The transition metal sulfide includes, but is not limited to, one or more of molybdenum sulfide, tungsten sulfide, and copper sulfide. The transition metal selenide includes, but is not limited to, one or more of molybdenum selenide and tungsten selenide. The doped or undoped nickel oxide is, for example, NiO. The doped or undoped molybdenum oxide is, for example, MoO₃. The doped or undoped tungsten oxide is, for example, WO₃. The doped or undoped vanadium oxide is, for example, V₂O₅. The doped or undoped chromium oxide is, for example, CrO₃. The doped or undoped copper oxide is, for example, one or more of CuO and Cu₂O.

A method for preparing each film layer in the light-emitting device may be realized by a conventional technique in the art, including but being not limited to a solution method and a deposition method. The solution method includes, but is not limited to, one or more of a spin coating method, a printing method, an ink jet printing method, a scratch coating method, a printing method, a dipping and pulling method, a soaking method, a spraying method, a roll coating method, a casting method, a slit coating method, and a strip coating method. The deposition method includes a chemical method and physical method, where the chemical method includes, but is not limited to, one or more of a chemical vapor deposition method, a continuous ion layer adsorption and reaction method, an anodic oxidation method, an electrolytic deposition method, and a co-precipitation method, and a physical method includes, but is not limited to, one or more of a thermal evaporation coating method, an electron beam evaporation coating method, a magnetron sputtering method, a multi-arc ion coating method, a physical vapor deposition method, an atomic layer deposition method, and a pulsed laser deposition method. When the solution method is configured to prepare a film layer, it is necessary to add a drying process to convert a wet film into a dry film.

The method for preparing the light-emitting device may further include other steps, for example, after preparing each film layer of the light-emitting device, it is necessary to perform an encapsulating process on the light-emitting device.

An embodiment of the present disclosure provides an electronic apparatus including the light-emitting device according to any one of embodiments of the present disclosure. The electronic apparatus may be any electronic product with a display function, including but being not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality helmet, or the like.

The following is a detailed description of technical proposals and beneficial effects of the present disclosure through specific embodiments and comparative examples. The following embodiments are only part of implementation examples of the present disclosure, and are not specifically limited to the present disclosure.

### Example 1

The present embodiment provides a preparation method for a doped metal oxide and a doped metal oxide prepared. The doped metal oxide includes magnesium and zinc. Along a radial direction from an interior to a surface of the doped metal oxide, a molar percentage of magnesium gradually decreases.

The preparation method for the doped metal oxide includes the following step S1.1, step S1.2, step S1.3, step S1.4, and step S1.5.

In step S1.1, 0.24 mmol of zinc acetate was dissolved in 60 mL of dimethyl sulfoxide and stirred at room temperature for 2 hours to obtain a zinc precursor.

In step S1.2, 0.06 mmol of magnesium acetate was dissolved in 60 mL of dimethyl sulfoxide and stirred at room temperature for 2 hours to obtain a magnesium precursor.

In step S1.3, 0.36 mmol of potassium hydroxide was dispersed in 100 mL of ethanol and stirred at room temperature for 2 hours to obtain an alkaline solution.

In step S1.4, within 60 minutes, 100 mL of the alkaline solution, 60 mL of the magnesium precursor and 12 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform acceleration manner, where an initial injection rate of the water was 8 mL/h, and an acceleration was 8 mL/h². After the injection, a reaction product was obtained by stirring at room temperature for 4 hours.

In step S1.5, a precipitant was added to the reaction product to form a precipitate, then a centrifugal separation was performed to collect the precipitate, and the precipitate was washed and dried sequentially to obtain a purified doped metal oxide.

### Example 2

The present embodiment provides a preparation method for a doped metal oxide and a doped metal oxide prepared. The doped metal oxide includes magnesium and zinc. Along a radial direction from an interior to a surface of the doped metal oxide, a molar percentage of magnesium gradually decreases.

Compared with the preparation method in Example 1, the preparation method for the doped metal oxide in the present embodiment was different in that step S1.4 was replaced with “within 60 minutes, 100 mL of the alkaline solution, 60 mL of the magnesium precursor and 5 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform acceleration manner, where an initial injection rate of the water was 3.3 mL/h, and an acceleration was 3.3 mL/h². After the injection, a reaction product was obtained by stirring at room temperature for 4 hours”.

### Example 3

The present embodiment provides a preparation method for a doped metal oxide and a doped metal oxide prepared. The doped metal oxide includes magnesium and zinc. Along a radial direction from an interior to a surface of the doped metal oxide, a molar percentage of magnesium gradually decreases.

Compared with the preparation method in Example 1, the preparation method for the doped metal oxide in the present embodiment was different in that step S1.4 was replaced with “within 60 minutes, 100 mL of the alkaline solution, 60 mL of the magnesium precursor and 21 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform acceleration manner, where an initial injection rate of the water was 14 mL/h, and an acceleration was 14 mL/h². After the injection, a reaction product was obtained by stirring at room temperature for 4 hours”.

### Example 4

The present embodiment provides a preparation method for a doped metal oxide and a doped metal oxide prepared. The doped metal oxide includes magnesium and zinc. Along a radial direction from an interior to a surface of the doped metal oxide, a molar percentage of magnesium gradually decreases.

Compared with the preparation method in Example 1, the preparation method for the doped metal oxide in the present embodiment was different in that step S1.4 was replaced with “within 60 minutes, 100 mL of the alkaline solution, 60 mL of the magnesium precursor and 4 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform acceleration manner, where an initial injection rate of the water was 2.67 mL/h, and an acceleration was 2.67 mL/h². After the injection, a reaction product was obtained by stirring at room temperature for 4 hours”.

### Example 5

The present embodiment provides a preparation method for a doped metal oxide and a doped metal oxide prepared. The doped metal oxide includes magnesium and zinc. Along a radial direction from an interior to a surface of the doped metal oxide, a molar percentage of magnesium gradually decreases.

Compared with the preparation method in Example 1, the preparation method for the doped metal oxide in the present embodiment was different in that step S1.4 was replaced with “within 60 minutes, 100 mL of the alkaline solution, 60 mL of the magnesium precursor and 24 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform acceleration manner, where an initial injection rate of the water was 16 mL/h, and an acceleration was 16 mL/h². After the injection, a reaction product was obtained by stirring at room temperature for 4 hours”.

### Example 6

The present embodiment provides a light-emitting device and a preparation method thereof. The light-emitting device is a quantum dot light emitting diode with an upright structure. Referring to FIG. 3, in a bottom-up direction, the light-emitting device 1 includes a substrate 10, an anode 11, a hole functional layer 15, an emission material layer 13, an electron functional layer 14, and a cathode 12 disposed sequentially in stack. The hole functional layer 15 is formed of a hole injection layer 151 and a hole transport layer 152, where the hole transport layer 152 is closer to the emission material layer 13 than the hole injection layer 151.

Materials and thicknesses of each layer in the light-emitting device 1 are described below.

A material of the substrate 10 is glass, and a thickness of the substrate 10 is 2 mm.

A material of the anode 11 is ITO, and a thickness of the anode 11 is 80 nm.

A material of the cathode 12 is Ag, and a thickness of the cathode 12 is 100 nm.

A material of the emission material layer 13 is a quantum dot of CdSe (core)/ZnS (outer shell) with an emission peak position of 465 nm, and a thickness of the emission material layer 13 is 30 nm.

A material of the electron functional layer 14 is the doped metal oxide prepared in Example 1, and a thickness of the electron functional layer 14 is 30 nm;

A material of the hole injection layer 151 is PEDOT:PSS, and a thickness of the hole injection layer 151 is 25 nm.

A material of the hole transport layer 152 is TFB, and a thickness of the hole transport layer 152 is 25 nm.

A method for preparing the light-emitting device includes the following step S6.1, step S6.2, step S6.3, step S6.4, step S6.5 and step S6.6.

In step S6.1, ITO was sputtered on one side of the substrate provided to obtain an ITO layer. A surface of the ITO layer was wiped with a cotton swab dipped in a small amount of soapy water to remove visible impurities on the surface. The substrate including the ITO layer was ultrasonically cleaned by deionized water for 15 minutes, acetone for 15 minutes, ethanol for 15 minutes and isopropyl alcohol for 15 minutes sequentially, and after drying, the substrate including the anode was formed by an ultraviolet-ozone surface treatment for 15 minutes.

In step S6.2, a PEDOT:PSS aqueous solution was spin-coated on one side of the anode away from the substrate under an air atmosphere at a normal temperature and a normal pressure, and then the hole injection layer was formed by heating at 150° C. for 30 minutes.

In step S6.3, a TFB-chlorobenzene solution with a concentration of 8 mg/mL was spin-coated on one side of the hole injection layer away from the anode under a nitrogen atmosphere at a normal temperature and a normal pressure, and then the hole functional layer 15 was formed by heating at 150° C. for 30 minutes.

In step S6.4, a CdSe/ZnS quantum dot-n-octane solution with a concentration of 25 mg/mL was spin-coated on one side of the hole transport layer away from the hole injection layer under a nitrogen atmosphere at a normal temperature and a normal pressure, and then the emission material layer was formed by heating at 60° C. for 5 minutes.

In step S6.5, the doped metal oxide prepared in Example 1 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes.

In step S6.6, a prefabricated device including the electron functional layer was placed in an evaporation chamber with an air pressure of 4× 10-6 mbar, then the cathode was formed on one side of the electron functional layer away from the emission material layer by evaporating silver through a mask plate, and finally an epoxy resin adhesive and a cover glass were used for encapsulation to obtain the light-emitting device.

### Example 7

The present embodiment provides a light-emitting device and a preparation method thereof. Compared with the light-emitting device of Example 6, the light-emitting device of the present embodiment is different only in that the material of the electron functional layer is replaced with the doped metal oxide prepared in Example 2.

Compared with the method for preparing the light-emitting device in Example 6, the method for preparing the light-emitting device of the present embodiment was different only in that step S6.5 was replaced with “the doped metal oxide prepared in Example 2 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Example 8

The present embodiment provides a light-emitting device and a preparation method thereof. Compared with the light-emitting device of Example 6, the light-emitting device of the present embodiment is different only in that the material of the electron functional layer is replaced with the doped metal oxide prepared in Example 3.

Compared with the method for preparing the light-emitting device in Example 6, the method for preparing the light-emitting device of the present embodiment was different in that step S6.5 was replaced with “the doped metal oxide prepared in Example 3 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Example 9

The present embodiment provides a light-emitting device and a preparation method thereof. Compared with the light-emitting device of Example 6, the light-emitting device of the present embodiment is different only in that the material of the electron functional layer is replaced with the doped metal oxide prepared in Example 4.

Compared with the method for preparing the light-emitting device in Example 6, the method for preparing the light-emitting device of the present embodiment was different in that step S6.5 was replaced with “the doped metal oxide prepared in Example 4 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Example 10

The present embodiment provides a light-emitting device and a preparation method thereof. Compared with the light-emitting device of Example 6, the light-emitting device of the present embodiment is different only in that the material of the electron functional layer is replaced with the doped metal oxide prepared in Example 5.

Compared with the method for preparing the light-emitting device in Example 6, the method for preparing the light-emitting device of the present embodiment was different in that step S6.5 was replaced with “the doped metal oxide prepared in Example 5 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Comparative Example 1

The present comparative embodiment provides a preparation method for a doped metal oxide and a doped metal oxide prepared. Compared with the preparation method in Example 1, the preparation method for the doped metal oxide in the present comparative embodiment was different in that step S1.4 was replaced with “within 60 minutes, 100 mL of the alkaline solution, 60 mL of the magnesium precursor and 12 mL of water were simultaneously and continuously injected into 60 mL of the zinc precursor. The alkaline solution, the magnesium precursor and the water were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h; the water was injected at a uniform rate, and an injection rate of the water was 12 mL/h. After the injection, a reaction product was obtained by stirring at room temperature for 4 hours”.

### Comparative Example 2

The present comparative embodiment provides a preparation method for a doped metal oxide and a doped metal oxide prepared. Compared with the preparation method in Example 1, the preparation method for the doped metal oxide in the present comparative embodiment was different in that step S1.4 was replaced with “within 60 minutes, 100 mL of the alkaline solution, and 60 mL of the magnesium precursor were simultaneously and continuously injected into 60 mL of the zinc precursor. The alkaline solution and the magnesium precursor were injected at a same start time and a same end time. During an injection process, the alkaline solution was injected at a uniform rate, and an injection rate of the alkaline solution was 100 mL/h; the magnesium precursor was injected at a uniform rate, and an injection rate of the magnesium precursor was 60 mL/h”.

### Comparative Example 3

The present comparative embodiment provides a light-emitting device and a preparation method thereof. Compared with the light-emitting device of Example 6, the light-emitting device of the present comparative embodiment is different only in that the material of the electron functional layer is replaced with the doped metal oxide prepared in Comparative Example 1.

Compared with the method for preparing the light-emitting device in Example 6, the method for preparing the light-emitting device of the present comparative embodiment was different in that step S6.5 was replaced with “the doped metal oxide prepared in Comparative Example 1 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Comparative Example 4

The present comparative embodiment provides a light-emitting device and a preparation method thereof. Compared with the light-emitting device of Example 6, the light-emitting device of the present comparative embodiment is different only in that the material of the electron functional layer is replaced with the doped metal oxide prepared in Comparative Example 2.

Compared with the method for preparing the light-emitting device in Example 6, the method for preparing the light-emitting device of the present comparative embodiment was different in that step S6.5 was replaced with “the doped metal oxide prepared in Comparative Example 2 was dispersed in ethanol to obtain a doped metal oxide-ethanol solution with a concentration of 30 mg/mL, then the doped metal oxide-ethanol solution was spin-coated on one side of the emission material layer away from the hole transport layer under a nitrogen atmosphere at a normal temperature and a normal pressure, and then the electron functional layer was formed by heating at 60° C. for 10 minutes”.

### Experimental Example 1

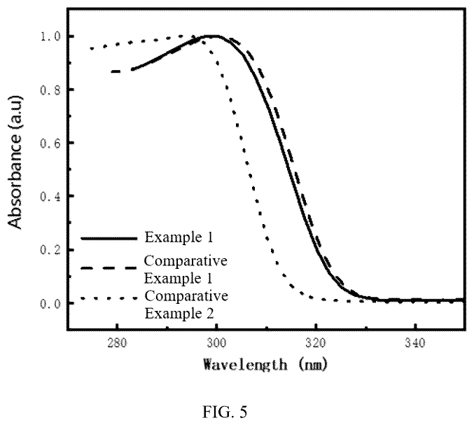

Ultraviolet absorption spectrums of the doped metal oxides prepared in Examples 1 to 5, Comparative Example 1 and Comparative Example 2 were respectively tested by an ultraviolet-visible spectrophotometer. FIG. 5 shows ultraviolet absorption spectrums of magnesium-doped zinc oxides prepared in Example 1, Comparative Example 1 and Comparative Example 2, and optical band gaps of doped metal oxides prepared in Examples 1 to 5, Comparative Example 1 and Comparative Example 2 were calculated by a Tauc plot method.

Optical band gaps of each doped metal oxide are shown in Table 1 below: Table 1 a list of optical band gaps of doped metal oxides prepared in Examples 1 to 5,

### Comparative Example 1 and Comparative Example 2

| | optical band gaps |
|---|---|
| serial number | (eV) |
| Example 1 | 3.86 |
| Example 2 | 3.93 |
| Example 3 | 3.82 |
| Example 4 | 3.93 |
| Example 5 | 3.80 |
| Comparative Example 1 | 3.85 |
| Comparative Example 2 | 3.96 |

As shown Table 1, optical band gaps of doped metal oxides in Examples 1 to 5 and Comparative Example 1 each are narrower than that of the doped metal oxide in Comparative Example 2. Additionally, based on optical band gaps of doped metal oxides in Examples 1 to 5 and Comparative Example 1, it can be observed that during a preparation of a doped metal oxide, an optical band gap of a doped metal oxide prepared is narrower as an amount of the water is more used in the preparation method of the doped metal oxide which may be attributed to a fact that when a solution-gel method is employed to prepare the doped metal oxide, introducing water into a reaction system may reduce a number of magnesium atoms doped into a crystal structure, thereby decreasing the optical bandgap of the doped metal oxide.

As can be seen from FIG. 5, compared with the maximum absorption peak wavelength of the doped metal oxide in Comparative Example 2, doped metal oxides in Example 1 and Comparative Example 1 have a different degree of “red shift” phenomenon, and a degree of “red shift” of the maximum absorption peak wavelength of the doped metal oxide in Example 1 is higher. The more obvious the “red shift” phenomenon is, the less magnesium atoms doped into a zinc oxide crystal structure. Specifically, a content of magnesium in the doped metal oxide in Comparative Example 2 is the highest, followed by Comparative Example 1, and a content of magnesium in the doped metal oxide in Example 1 is the lowest. This indicates that during a preparation of a doped metal oxide, a number of magnesium atoms doped into the zinc oxide crystal structure may be regulated by injecting water and adjusting an injection rate of the water, thereby controlling a distribution of magnesium in the doped metal oxide prepared which is convenient to regulate an energy level structure of the doped metal oxide.

### Experimental Example 2

An electron mobility and a current density were tested by a single-electron device. The single-electron device consisted of a substrate, an anode, an emission material layer, an electron functional layer, and a cathode disposed in stack sequentially. There were seven single-electron devices to be tested, corresponding to a first single-electron device to a seventh single-electron device. Structural compositions of the substrate, the anode, the emission material layer, the electron functional layer, and the cathode in each of the first single-electron device to the seventh single-electron device were the same as those of corresponding film layers in Example 7. A material of the electron functional layer in each of the first single-electron device to the seventh single-electron device was the doped metal oxide prepared in Examples 1 to 5, Comparative Example 1, and Comparative Example 2, respectively. For example, a material of the electron functional layer in the first single-electron device was the doped metal oxide prepared in Example 1, a material of the electron functional layer in the second single-electron device was the doped metal oxide prepared in Example 2, and so on. A material of the electron functional layer in the seventh single-electron device was the doped metal oxide prepared in Comparative Example 2.

A specific testing method was as follows: a set of QLED efficiency test system was built by controlling QE PRO and Keithley 2400 through Lab View. Current density-voltage characteristic curves of each single-electron device were tested by the system, and current density values (J, mA/cm²) of each single-electron device at a working voltage of 8 V were recorded and compared. Space charge limited current (SCLC) regions in current density-voltage curves of each single-electron device were obtained, and then the electron mobility was calculated according to a formula J=(9/8)εᵣε₀μₑV²/d³, where J represents a current density in mA/cm², εᵣ represents a relative dielectric constant, ε₀ represents a vacuum dielectric constant, μₑ represents a hole mobility in cm²/V·s, V represents a driving voltage in V, and d represents a thickness of the electron functional layer in nm.

Performance test results of each single-electronic device are shown in Table 2 below:

### Table 2 a List of Performance Test Results of the First Single-Electron Device to the Seventh Single-Electron Device

| | J | μe |
|---|---|---|
| serial number | (mA/cm²) | (×10⁻⁶ cm²V⁻¹s⁻¹) |
| the first single-electron device | 210 | 524 |
| the second single-electron device | 142 | 365 |
| the third single-electron device | 226 | 637 |
| the fourth single-electron device | 120 | 280 |
| the fifth single-electron device | 235 | 612 |
| the sixth single-electron device | 87 | 210 |
| the seventh single-electron device | 14 | 47 |

As shown in Table 2, compared with the sixth single-electron device and the seventh single-electron device, the first single-electron device to the fifth single-electron device exhibit better electrical performance. Specifically, current density values at a working voltage of 8 V and electron mobilities of the first single-electron device to the fifth single-electron device are higher. Taking the first single-electron device and the seventh single-electron device as examples, a current density value of the first single-electron device at the working voltage of 8 Vis 15 times that of the seventh single-electron device, and the electron mobility of the first single-electron device is 11 times that of the seventh single-electron device.

Therefore, in the first single-electron device to the fifth single-electron device, a material of the electron functional layer is a magnesium-doped zinc oxide, and during a preparation process of the magnesium-doped zinc oxide, water is injected into a reaction system in a uniformly accelerated manner, so that along a direction from an interior to a surface of the magnesium-doped zinc oxide, a molar percentage of magnesium gradually decreases, and a stepped energy level structure is formed between the electron functional layer and the cathode which is beneficial for electron injection.

In the sixth single-electron device, a material of the electron functional layer is a magnesium-doped zinc oxide. During a preparation process of the magnesium-doped zinc oxide, water is injected into a reaction system in a uniform manner, so that a molar percentage of magnesium almost does not change along a direction from an interior to a surface of the magnesium-doped zinc oxide which prevents a formation of a stepped energy level structure between the electron functional layer and the cathode, and a presence of water reduces a number of magnesium atoms doped into a crystal structure, leading to an unsatisfactory electrical performance of the sixth single-electron device.

In the seventh single-electron device, a material of the electron functional layer is a magnesium-doped zinc oxide. During a preparation process of the magnesium-doped zinc oxide, an absence of water leads to a higher number of magnesium atoms doped into a crystal structure and prevents a formation of a stepped energy level structure between the electron functional layer and the cathode, resulting in a high conduction band energy level of the magnesium-doped zinc oxide which is not conducive to electron injection.

### Experimental Example 3

Performances of light-emitting devices in Examples 6 to 10, Comparative Example 3, and Comparative Example 4 were tested, and performance test items were as follows:

### (1) Detection of a Current Efficiency

A light-emitting area was set to 2 mm×2 mm=4 mm². Luminance values of a light-emitting device in a range of driving voltages from 0 V to 8 V were intermittently collected, where a voltage value of an initial luminance collected was 3 V, and a luminance value was collected every 0.2 V. A luminance value collected every time was divided by a corresponding current density to obtain a current efficiency of the light-emitting device, thus the maximum current efficiency (C.Eₘₐₓ, cd/A) was obtained.

### (2) Detection of a Lifetime T95@1000 nit

Under a drive of a constant current (2 mA), electroluminescence lifetime analyses of light-emitting devices of Examples 15 to 28 and Comparative Example were performed by a 128-channel QLED lifetime testing system. A time (T95, h) required for each light-emitting device to decay from the maximum luminance to 95% was recorded, and a time (T95@1000 nit, h) required for each light-emitting device to decay from 100% to 95% at a luminance of 1000 nit maximum luminance was calculated by an attenuation fitting formula.

Performance test datas of each light-emitting device are shown in Table 3 below:

### Table 3 a List of Performance Test Datas of Light Emitting Devices of Examples 6 to 10, Comparative Example 3, and Comparative Example 4

| | C.Eₘₐₓ | T95@1000 nit |
|---|---|---|
| serial number | (cd/A) | (h) |
| Example 6 | 18 | 52 |
| Example 7 | 15 | 55 |
| Example 8 | 14 | 48 |
| Example 9 | 8 | 30 |
| Example 10 | 7 | 25 |
| Comparative | 6 | 12 |
| Example 3 | | |
| Comparative | 3 | 8 |
| Example 4 | | |

As can be seen from Table 3, compared with comprehensive performances of light-emitting devices of Comparative Examples 3 and 4, comprehensive performances of light-emitting devices of Examples 6 to 10 exhibit significant advantages. Taking light-emitting devices of Example 6 and Comparative Example 4 as examples, a C.Eₘₐₓ of the light-emitting device of Example 6 is six times a C.Eₘₐₓ of the light-emitting device of Comparative Example 4, and a T95@1000 nit of the light-emitting device of Example 6 is thirteen times a T95@1000 nit of the light-emitting device of Comparative Example 4.

In summary, using a magnesium-doped zinc oxide as a material of the electron functional layer, and gradually decreasing a molar percentage of magnesium along a radial direction from an interior to a surface of the magnesium-doped zinc oxide, is beneficial to further improve a current efficiency of a light-emitting device. It may be attributed to reasons: on the one hand, a stepped energy level structure is formed between the electron functional layer and the cathode, and a mole percentage of magnesium in a surface of the magnesium-doped zinc oxide is low, effectively lowering an electron injection barrier, promoting electron injection and improving an electron injection level of the light-emitting device; On the other hand, compared with zinc oxide, a band gap of the magnesium-doped zinc oxide is wider which is more conducive to limiting excitons to the emission material layer.

The preparation method for a doped metal oxide, and a light-emitting device including the doped metal oxide provided by embodiments of the present disclosure are described in detail above. Specific embodiments have been applied herein to illustrate principles and implement measures. Descriptions of embodiments above are provided merely to help understand a method and a core idea of the present disclosure. Meanwhile, for those skilled in the art, based on ideas of the present disclosure, there may be changes in specific implementation manners and application scopes. In conclusion, a content of the present specification may not be construed as a limitation to the present disclosure.

1. A preparation method for a doped metal oxide, comprising steps of:
providing a first solution comprising a first metal salt, a second solution comprising a second metal salt, and a third solution comprising an alkali, wherein the first metal salt comprises a first metal element, and the second metal salt comprises a second metal element; and
mixing the second solution, the third solution, water and the first solution for a reaction to obtain a doped metal oxide comprising the first metal element and the second metal element;
wherein a solubility product of a hydroxide of the second metal element in water is greater than a solubility product of a hydroxide of the first metal element in water at a same temperature.

2. The preparation method for the doped metal oxide according to claim 1, wherein a step of mixing the second solution, the third solution, the water and the first solution comprises injecting the second solution, the third solution and the water into the first solution;
wherein the second solution, the third solution and the water are injected at a same start time and a same end time, and during an injection process, the second solution and the third solution are each injected at a uniform rate, while the water is injected at a non-uniform rate.

3. The preparation method for the doped metal oxide according to claim 2, wherein a final injection rate of the water is greater than an initial injection rate of the water;
during a process of injecting the water, an injection rate of the water gradually increases;
the final injection rate of the water is 1.5 to 3 times the initial injection rate of the water.

4. The preparation method for the doped metal oxide according to claim 2, wherein a final injection rate of the water is less than an initial injection rate of the water;
during a process of injecting the water, an injection rate of the water gradually decreases;
the initial injection rate of the water is 1.5 to 3 times the final injection rate of the water.

5. The preparation method for the doped metal oxide according to claim 2, wherein a total time of injection ranges from 5 minutes to 60 minutes.

6. The preparation method for the doped metal oxide according to claim 1, wherein the first metal element is selected from Zn, and the second metal element is selected from Mg, Ca, Mn or Ba.

7. The preparation method for the doped metal oxide according to claim 1, wherein the first metal element is selected from Al, and the second metal element is selected from Zn, Mg, Ca, Mn, Ba or Sn.

8. The preparation method for the doped metal oxide according to claim 1, wherein the first metal element is selected from Sn, and the second metal element is selected from Zn, Mg, Ca, Mn or Ba.

9. The preparation method for the doped metal oxide according to claim 1, wherein the first metal element is selected from Ti, and the second metal element is selected from Zn, Mg, Ca, Mn, Ba, Sn or Al.

10. The preparation method for the doped metal oxide according to claim 1, wherein a conduction band of a first metal oxide formed by the first metal element is smaller than a conduction band of a second metal oxide formed by the second metal element.

11. The preparation method for the doped metal oxide according to claim 1, wherein in the step of mixing the second solution, the third solution, the water and the first solution, a molar ratio of the second metal element in the second solution to the first metal element in the first solution ranges from 1:4 to 1:20, a molar ratio of the second metal element in the second solution to the water ranges from 1:4 to 1:20, and a molar ratio of the first metal element in the first solution to hydroxyl of the alkali in the third solution ranges from 1:0.8 to 1:4;
a concentration of the first metal salt in the first solution ranges from 0.1 mmol/mL to 0.5 mmol/mL;
a concentration of the second metal salt in the second solution ranges from 0.1 mmol/mL to 0.5 mmol/mL;
a concentration of the alkali in the third solution ranges from 0.1 mmol/mL to 1.0 mmol/mL;
the reaction is performed at a temperature ranging from 0° C. to 70° C.;
a time of the reaction ranges from 5 minutes to 24 hours.

12. A doped metal oxide, wherein the doped metal oxide is prepared by a preparation method as follows:
providing a first solution comprising a first metal salt, a second solution comprising a second metal salt, and a third solution comprising an alkali, wherein the first metal salt comprises a first metal element, and the second metal salt comprises a second metal element; and
mixing the second solution, the third solution, water and the first solution for a reaction to obtain a doped metal oxide comprising the first metal element and the second metal element;
wherein a solubility product of a hydroxide of the second metal element in water is greater than a solubility product of a hydroxide of the first metal element in water at a same temperature.

13. The doped metal oxide according to claim 12, wherein an average particle size of the doped metal oxide ranges from 2 nm to 20 nm;
a band gap of the doped metal oxide ranges from 3.7 eV to 4.5 eV.

14. The doped metal oxide according to claim 12, wherein a molar percentage of the second element gradually increases or decreases in a direction from an interior to a surface of the doped metal oxide.

15. A light-emitting device, comprising:
an anode;
a cathode disposed opposite the anode;
an emission material layer disposed between the anode and the cathode; and
an electron functional layer disposed between the cathode and the emission material layer;
wherein a material of the electron functional layer comprises a doped metal oxide prepared by a preparation method as follows:
providing a first solution comprising a first metal salt, a second solution comprising a second metal salt, and a third solution comprising an alkali, wherein the first metal salt comprises a first metal element, and the second metal salt comprises a second metal element; and
mixing the second solution, the third solution, water and the first solution for a reaction to obtain a doped metal oxide comprising the first metal element and the second metal element;
wherein a solubility product of a hydroxide of the second metal element in water is greater than a solubility product of a hydroxide of the first metal element in water at a same temperature.

16. The light-emitting device according to claim 15, wherein
an average particle size of the doped metal oxide ranges from 2 nm to 20 nm;
a band gap of the doped metal oxide ranges from 3.7 eV to 4.5 eV;
a molar percentage of the second element gradually increases or decreases in a direction from an interior to a surface of the doped metal oxide.

17. The light-emitting device according to claim 15, wherein a conduction band of a first metal oxide formed by the first metal element is smaller than a conduction band of a second metal oxide formed by the second metal element.

18. The light-emitting device according to claim 15, wherein the first metal element is selected from Zn, and the second metal element is selected from Mg, Ca, Mn or Ba; or
the first metal element is selected from Al, and the second metal element is selected from Zn, Mg, Ca, Mn, Ba or Sn; or
the first metal element is selected from Sn, and the second metal element is selected from Zn, Mg, Ca, Mn or Ba; or
the first metal element is selected from Ti, and the second metal element is selected from Zn, Mg, Ca, Mn, Ba, Sn or Al.

19. The light-emitting device according to claim 15, wherein a material of the emission material layer is selected from an organic light-emitting material or a quantum dot; wherein the organic light-emitting material is selected from one or more of 4, 4′-bis (N-carbazole)-1, 1′-biphenyl: tris [2-(p-tolyl)pyridinate iridium (III), 4, 4′, 4′-tris (carbazol-9-yl) triphenylamine: tris [2-(p-tolyl)pyridinate iridium, a diarylanthracene derivative, a stilbene aromatic derivative, a pyrene derivative, a fluorene derivative, a TBPe fluorescent material, a TTPX fluorescent material, a TBRb fluorescent material, a DBP fluorescent material, a delayed fluorescent material, a TTA material, a thermally activated delayed material, a polymer comprising a B-N covalent bond, a hybrid local charge transfer excited state material, and an exciplex luminescent material; the quantum dot is selected from one or more of a quantum dot with a single component, a quantum dot with a core-shell structure, an inorganic perovskite quantum dot, an organic perovskite quantum dot, and an organic-inorganic hybrid perovskite quantum dot; a material of the quantum dot with the single component, a material of a core of the quantum dot with the core-shell structure, and a material of a shell layer of the quantum dot with the core-shell structure are each independently selected from one or more of a group II-VI compound, a group III-V compound, a group IV-VI compound, and a group I-III-VI compound, wherein the group II-VI compound is selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe, the group III-V compound is selected from one or more of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, the group IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe, and the group I-III-VI compound is selected from one or more of CuInS, CuInSe, and AgInS; the inorganic perovskite quantum dot has a general structural formula of AMX₃, where A is Cs⁺, M is a divalent metal cation selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion; the organic perovskite quantum dot has a general structural formula of CMX₃, where C is a formamidinyl; the organic-inorganic hybrid perovskite quantum dot has a general structural formula of BMX₃, where B is an organic amine cation;
materials of the anode and the cathode are independently selected from one or more of a metal, a carbon material, and a third metal oxide, wherein the metal is selected from one or more of Al, Ag, Cu, Mo, Au, Ba, Ca, and Mg, the carbon material is selected from one or more of graphite, carbon nanotubes, graphene, and carbon fibers, and the third metal oxide is selected from one or more of indium-doped tin oxide, fluorine-doped tin oxide, antimony-doped tin oxide, aluminum-doped zinc oxide, gallium-doped zinc oxide, indium-doped zinc oxide, and magnesium-doped zinc oxide.

20. The light-emitting device according to claim 15, wherein the light-emitting device further comprises a hole functional layer comprising a hole injection layer and a hole transport layer disposed between the emission material layer and the anode where the hole injection layer is closer to the anode than the hole transport layer, and the hole transport layer is closer to the emission material layer than the hole injection layer;
wherein a material of the hole injection layer or a material of the hole transport layer is selected from one or more of poly (3, 4-ethylenedioxythiophene)poly (styrenesulfonate), copper(II) phthalocyanine, titanyl phthalocyanine, poly (9,9-dioctylfluorene-co-N-(4-butylphenyl) diphenylamine), poly (3-hexylthiophene-2,5-diyl), poly (n-vinylcarbazole), poly [N, N′-bis (4-butylphenyl)-N, N′-bis (phenyl)benzi, poly (N, N′-bis (4-butylphenyl)-N, N′-diphenyl-1,4-benzenediamine-co-9,9-dioctylfluorene, poly [4, 4′, 4″-tris (N-3-methylphenyl-N-phenylamino) triphenylamine], poly [4, 4′, 4″-tris[2-naphthyl (phenyl) amino] triphenylamine], 2, 3, 5, 6-tetrafluoro-7, 7, 8, 8-tetracyanoquinodimethane, hexaazatriphenylenehexacabonitrile, poly (4, 4′-N, N′-dicarbazolyl-biphenyl), poly (4, 4′-bis (1-naphthyl)-1,1′-biphenyl-4, 4′-diamine), poly (4, 4′-Bis (N-carbazolyl)-1, 1′-biphenyl), poly (4, 4′, 4″-tris (carbazol-9-yl)-triphenylamine), poly (N, N′-diphenyl-N, N′-bis (3-methylphenyl)-(1,1′-biphenyl)-4,4′-diamine), poly (N,N′-bis (3-methylphenyl)-N, N′-bis (phenyl)-spiro), poly (N, N′-bis (4-(N, N′-diphenyl-amino)phenyl)-N, N′-diphenylbenzidine), poly (4, 4′, 4′-tris (N-carbazolyl)-triphenylamine), poly [4, 4′, 4″-tris (N-3-methylphenyl-N-phenylamino) triphenylamine], poly (9,9-dioctylfluorene-co-N-(4-butylphenyl) diphenylamine), poly (4-butylphenyl-diphenylamine), polyaniline, polypyrrole, poly (p) phenylene vinylidene, poly (phenylenevinylene), poly (2-methoxy-5-(2-ethylhexyloxy)-1, 4-phenylenevinylene), poly(2-methoxy-5-(3′, 7′-dimethyloctyloxy)-1, 4-phenylenevinylene), aromatic tertiary amines, 4, 4′-bis (p-carbazolyl)-1,1′-biphenyl, N, N, N′, N′-tetraarylbenzidine, poly (N-vinylcarbazole) and its derivatives, polymethacrylates and its derivatives, poly (9,9-octylfluorene) and its derivatives, poly (spirofluorene) and its derivatives, poly (N, N′-bis (naphthalen-1-yl)-N, N′-diphenylbenzidine, doped or undoped graphene, C60, doped or undoped nickel oxide, doped or undoped molybdenum oxide, doped or undoped tungsten oxide, doped or undoped vanadium oxide, doped or undoped P-type gallium nitride, doped or undoped chromium oxide, doped or undoped copper oxide, a transition metal sulfide, and a transition metal selenide.
